(19) United States
(12) Patent Application Publication
(10) Pub. No.: US 2025/0155658 A1
(43) Pub. Date: May 15, 2025

(54) LASER ASSEMBLY AND METHOD FOR MANUFACTURING SAME, LASER MODULE, OPTICAL ENGINE, AND XR GLASSES

(71) Applicant: TDK Corporation, Tokyo (JP)

(72) Inventors: Takashi HONDA, Tokyo (JP); Ryohei Fukuzaki, Hong Kong (CN); Tsuyoshi Komaki, Tokyo (JP)

(73) Assignee: TDK Corporation, Tokyo (JP)

(21) Appl. No.: 18/944,725

(22) Filed: Nov. 12, 2024

(30) Foreign Application Priority Data
Nov. 13, 2023 (JP) 2023-192691

(51) Int. Cl. G02B 6/42; G02B 6/12; G02B 6/132; G02B 26/08; G02B 27/01; H01S 5/02315

(52) U.S. Cl. CPC G02B 6/4245; G02B 6/132; G02B 26/0816; G02B 27/0172; H01S 5/02315; G02B 2006/12038; G02B 2006/1204; G02B 2006/12121; G02B 2006/12126; G02B 2027/0178

(57) ABSTRACT

A laser assembly of the present invention includes a plurality of laser element bases in which laser elements are installed on main surfaces, an optical waveguiding substrate in which an optical waveguiding layer is provided on a main surface, a plurality of spacer layers which are disposed away from each other at positions corresponding to the bases on a bonding surface of the substrate, and a plurality of metal laminate films which bond bonding surfaces of the plurality of laser element bases and the bonding surface of the optical waveguiding substrate. The plurality of metal laminate films are respectively disposed on the plurality of spacer layers and have a plurality of first metal films and second metal films that are disposed on the bonding surfaces of the plurality of laser element bases and made of metals capable of being eutectic with metals constituting the first metal films.

### CROSS-REFERENCE TO RELATED APPLICATION

Priority is claimed on Japanese Patent Application No. 2023-192691, filed Nov. 13, 2023, the content of which is incorporated herein by reference.

### BACKGROUND OF THE INVENTION

### Field of the Invention

The present invention relates to a laser assembly and a method for manufacturing the same, a laser module, an optical engine, and XR glasses.

### Description of Related Art

XR glasses such as augmented reality (AR) glasses and virtual reality (VR) glasses are being expected to become compact wearable devices. The key to the widespread use of wearable devices such as AR glasses and VR glasses is to miniaturize them such that each function fits into a normal glasses-type size.

### PATENT DOCUMENT

[Patent Document 1] PCT International Publication No. WO2021/149450

### SUMMARY OF THE INVENTION

Patent Document 1 discloses an integrated optical device that is miniaturized by bonding bases holding laser elements to a substrate provided with optical waveguides on a surface thereof with light emission positions of the laser elements and positions of the optical waveguides in an accurately aligned state with metal layers therebetween.

In a constitution in which a base and a substrate are bonded with a metal layer therebetween, a bonding strength is improved compared to a constitution in which they are bonded using an adhesive, and temperature dependency of the bonding strength is also curbed.

FIG. 15 is an explanatory schematic plan view of the integrated optical device disclosed in Patent Document 1. FIGS. 16A and 16B are schematic perspective views respectively showing bases holding laser elements (laser element base) and a substrate provided with optical waveguides on a surface thereof (optical waveguiding substrate), disclosed in Patent Document 1, in a state before they are bonded. FIG. 16A is a schematic perspective view of bases holding laser elements, and FIG. 16B is a schematic perspective view of a substrate provided with optical waveguides on a surface thereof.

Regarding the reference signs in the diagrams, the same reference signs are used for constituent elements similar to constituent elements of a laser assembly of the present embodiment which will be described below, and description thereof will be suitably omitted thereafter.

The integrated optical device shown in the diagrams includes three laser elements 30-1, 30-2, and 30-3, three bases 20 (20-1, 20-2, and 20-3) in which laser elements 30 are respectively placed on main surfaces 21-1, 21-2, and 21-3 and which are individually disposed away from each other, an optical waveguiding layer 50 which has optical waveguides 51 for waveguiding laser light emitted from the laser elements 30-1, 30-2, and 30-3, a substrate 40 which is provided with the optical waveguiding layer 50 on a surface thereof, and metal films which bond the bases 20 (20-1, 20-2, and 20-3) and the substrate 40.

In the integrated optical device shown in the diagrams, the metal films have a three-layer structure, which is constituted of metal layers 74 (74-1, 74-2, and 74-3) disposed on respective bonding surfaces 22 (22-1, 22-2, and 22-3) of the plurality of individual bases 20, a metal layer 172 subjected to film formation continuously in a strip shape on a bonding surface 42 of the substrate 40, and a metal layer 173 subjected to film formation continuously in a strip shape in a manner of overlapping the metal layer 172 from above.

In this manner, light emission positions of the laser elements and incidence port positions of the optical waveguides can be accurately aligned by bonding the bases holding the laser elements and the substrate provided with the optical waveguides via metal bonds.

When bonding is performed, metal films subjected to film formation on the bases and the substrate are caused to melt at a high temperature and are brought into contact with each other by applying a predetermined pressure to form metal bonds, thereby completing bonding. Here, when the metal films are caused to melt at a high temperature to generate metal bonds, since they are pressed with a predetermined pressure, there is concern that melted metal may leak out through voids between the bases and the substrate. Flat bonding surfaces allow the melted metal to be likely to flow. When melted metal leaks out through the voids, there is concern that it may form metal balls or may come into contact with other metal members and constitute a current path, and in this case, device failure or performance degradation will be caused.

The present invention has been made in consideration of the foregoing circumstances, and an object thereof is to provide a laser assembly, which is constituted to maintain predetermined gaps between laser element bases and an optical waveguiding substrate, and a method for manufacturing the same, a laser module, an optical engine, and XR glasses.

In order to resolve the foregoing problems, the present invention provides the following means.

According to Aspect 1 of the present invention, a laser assembly includes a plurality of laser elements, a plurality of laser element bases which have a main surface and a bonding surface and in which the plurality of laser elements are respectively installed on the main surfaces, an optical waveguiding substrate which has a main surface and a bonding surface and in which an optical waveguiding layer is provided with optical waveguides for waveguiding laser light emitted from the plurality of laser elements on the main surface, a plurality of spacer layers which are disposed away from each other at positions respectively corresponding to the plurality of laser element bases on the bonding surface of the optical waveguiding substrate, and a plurality of metal laminate films which bond the bonding surfaces of the plurality of laser element bases and the bonding surface of the optical waveguiding substrate. The plurality of metal laminate films are respectively disposed on the plurality of spacer layers and have a plurality of first metal films and second metal films that are disposed on the bonding surfaces of the plurality of laser element bases and made of metals capable of being eutectic with metals constituting the first metal films.

According to Aspect 2 of the present invention, in the laser assembly according to Aspect 1, the first metal films are made of Sn or an alloy containing Sn, and the second metal films are made of a metal selected from the group consisting of Au, Si, Al, Ni, Zn, Pt, and alloys of theses.

According to Aspect 3 of the present invention, in the laser assembly according to Aspect 1 or 2, the spacer layers have a thickness of 0.1 μm or larger.

According to Aspect 4 of the present invention, in the laser assembly according to any one of Aspects 1 to 3, the spacer layers are made of a metal selected from the group consisting of Ta, Ti, Ni, Ta/Pt, Ti/Pt, and Ni/Pt.

According to Aspect 5 of the present invention, in the laser assembly according to any one of Aspects 1 to 3, the spacer layers are made of an oxide.

According to Aspect 6 of the present invention, in the laser assembly according to any one of Aspects 1 to 5, the second metal films are formed to have a larger area than the first metal films.

According to Aspect 7 of the present invention, in the laser assembly according to any one of Aspects 1 to 6, the bonding surface of the optical waveguiding substrate includes an antireflection film, and the spacer layers are formed on the antireflection film.

According to Aspect 8 of the present invention, in the laser assembly according to any one of Aspects 1 to 7, the optical waveguiding layer is a planar lightwave circuit (PLC) made of a glass material.

According to Aspect 9 of the present invention, in the laser assembly according to any one of Aspects 1 to 7, the optical waveguiding layer is a PLC constituted of a lithium niobate film.

According to Aspect 10 of the present invention, there is provided a laser module in which the laser assembly according to either Aspect 8 or 9 is accommodated inside a package.

According to Aspect 11 of the present invention, an optical engine includes the laser module according to Aspect 10, and an optical scanning mirror for scanning light emitted from the laser module.

According to Aspect 12 of the present invention, XR glasses include the optical engine according to Aspect 11.

According to Aspect 13 of the present invention, a method for manufacturing a laser assembly includes an optical waveguiding substrate producing step of sequentially forming a plurality of spacer layers and first metal films on a bonding surface of an optical waveguiding substrate, a laser element base producing step of forming second metal films on bonding surfaces of laser element bases, and a bonding step of performing eutectic bonding of the laser element bases and the optical waveguiding substrate after the optical waveguiding substrate producing step and the laser element base producing step.

According to Aspect 14 of the present invention, in the method for manufacturing a laser assembly according to Aspect 13, in the optical waveguiding substrate producing step, the spacer layers and the first metal films are formed using a photoresist mask having a plurality of holes corresponding to a pattern of the plurality of spacer layers installed away from each other on the bonding surface of the optical waveguiding substrate, and in the bonding step, eutectic bonding of the first metal films of the optical waveguiding substrate and the second metal films of the laser element bases is performed using active alignment bonding.

According to the laser assembly of the present invention, it is possible to provide a laser assembly which is constituted to maintain predetermined gaps between laser element bases and an optical waveguiding substrate.

### BRIEF DESCRIPTION OF THE DRAWINGS

FIG. 1 is a schematic plan view of a part of a laser assembly according to the present embodiment.

FIG. 2 is a schematic cross-sectional view cut along line A-A′ in the laser assembly shown in FIG. 1.

FIG. 3A is a schematic perspective view of laser element bases before the laser element bases and an optical waveguiding substrate are bonded.

FIG. 3B is a schematic perspective view of the optical waveguiding substrate before the laser element bases and the optical waveguiding substrate are bonded.

FIG. 4 is a schematic cross-sectional view cut along line B-B′ in the laser assembly shown in FIG. 1.

FIG. 5A is a schematic view showing a step of bonding the laser element bases and the optical waveguiding substrate, showing a state before bonding.

FIG. 5B is a schematic view showing the step of bonding the laser element bases and the optical waveguiding substrate, showing a state after bonding.

FIG. 6 is a schematic view showing a bonding portion having characteristics different from those shown in FIG. 5B.

FIG. 7A is a schematic cross-sectional view showing an example of the laser assembly in which an antireflection film is provided on a bonding surface of the optical waveguiding substrate.

FIG. 7B is a schematic cross-sectional view showing another example of the laser assembly in which the antireflection film is provided on the bonding surface of the optical waveguiding substrate.

FIG. 8 is a schematic plan view of a laser module according to the present embodiment.

FIG. 9 is a view showing a cross section of the laser assembly disposed inside the laser module shown in FIG. 8 of which a part is cut along an X-Z plane.

FIG. 10 is a schematic plan view of a state in which a cover is removed from a laser module accommodating a laser assembly that has the optical waveguiding substrate including an optical waveguiding layer constituted of a lithium niobate film.

FIG. 11 is a schematic plan view of the laser assembly shown in FIG. 10 seen from an emission surface for visible laser light and near infrared laser light.

FIG. 12 is an explanatory conceptual diagram of XR glasses according to the present embodiment.

FIG. 13 is a conceptual diagram showing a situation in which an image is directly projected onto the retina by laser light emitted from the laser module according to the embodiment.

FIG. 14A is a flowchart of an optical waveguiding substrate producing step.

FIG. 14B is a flowchart of a laser element base producing step.

FIG. 14C is a flowchart of a bonding step.

FIG. 15 is a schematic plan view of a part of an integrated optical device.

FIG. 16A is a schematic perspective view of the laser element bases on which three laser elements included in the integrated optical device shown in FIG. 15 are placed.

FIG. 16B is a schematic perspective view of the optical waveguiding substrate included in the integrated optical device shown in FIG. 15.

### DETAILED DESCRIPTION OF THE INVENTION

Hereinafter, an embodiment will be described in detail suitably with reference to the drawings. In the drawings used in the following description, in order to make characteristics easy to understand, characteristic portions may be shown in an enlarged manner for the sake of convenience, and dimensional ratios or the like of each constituent element may differ from actual values thereof. Materials, dimensions, and the like shown in the following description are merely exemplary examples. The present invention is not limited thereto and can be suitably changed and performed within a range in which the effects of the present invention are exhibited.

### [Laser Assembly]

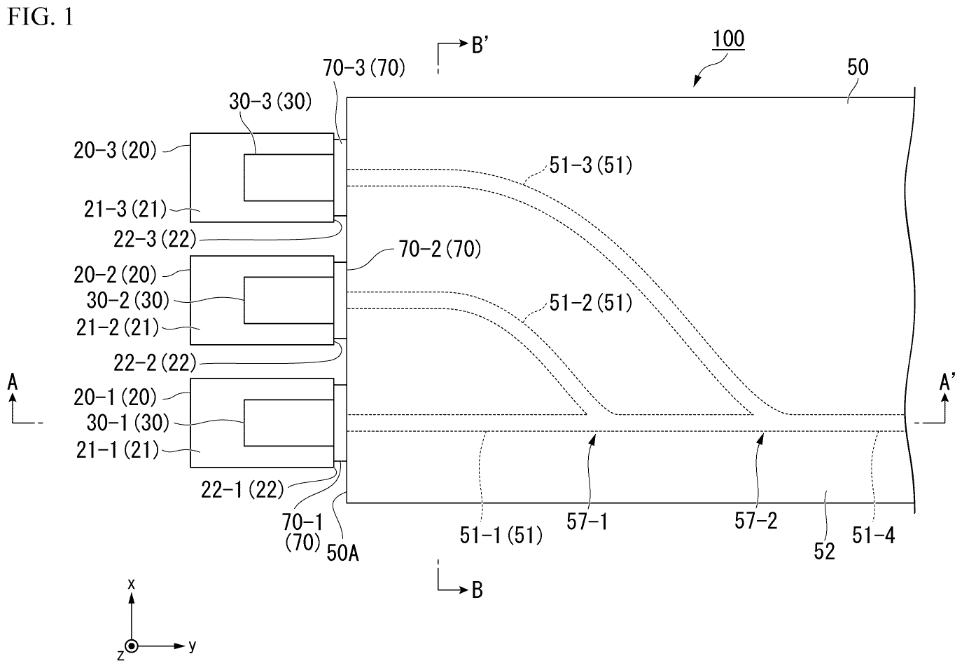

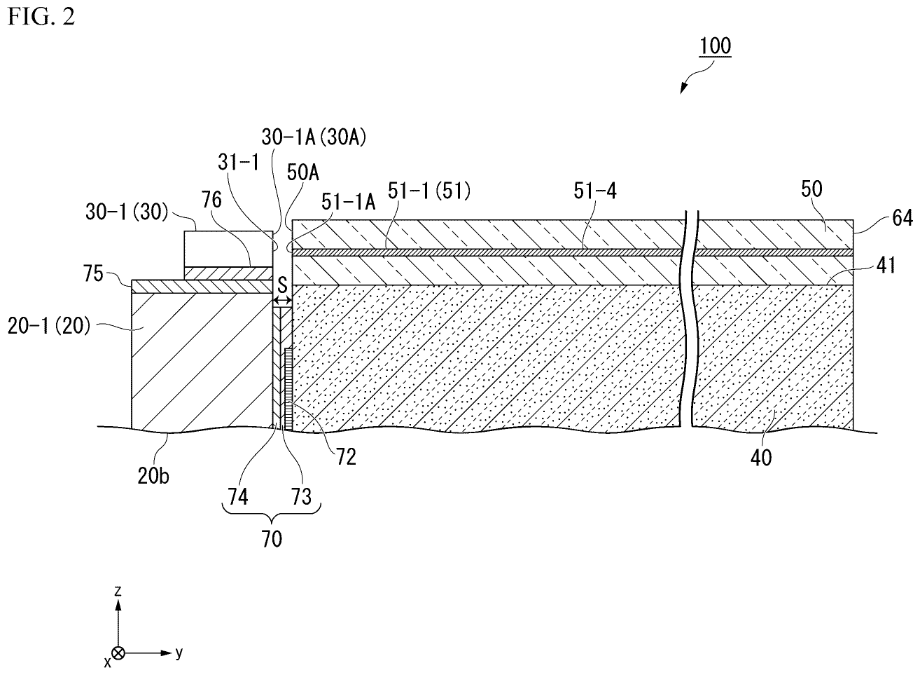

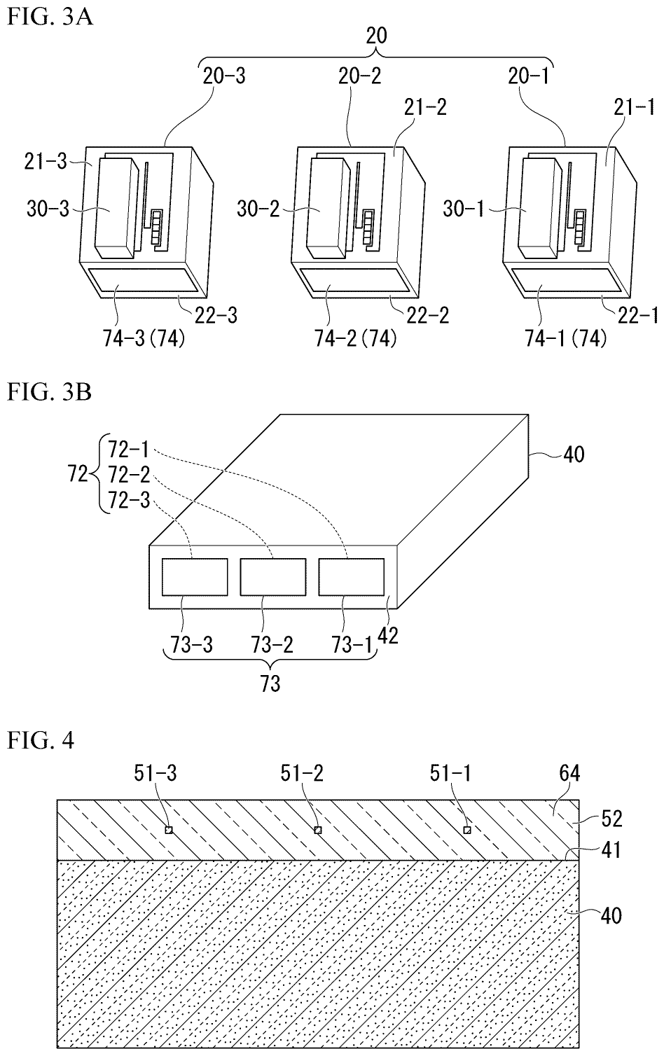

FIG. 1 is a schematic plan view of a part of a laser assembly of the present embodiment. FIG. 2 is a schematic cross-sectional view cut along line A-A′ in the laser assembly shown in FIG. 1. FIGS. 3A and 3B are schematic perspective views respectively showing laser element bases and an optical waveguiding substrate before being bonded. FIG. 3A is a schematic perspective view of the laser element bases, and FIG. 3B is a schematic perspective view of the optical waveguiding substrate. FIG. 4 is a schematic cross-sectional view cut along line B-B′ in the laser assembly shown in FIG. 1.

A laser assembly 100 shown in FIG. 1 includes a plurality of laser elements 30 (30-1, 30-2, and 30-3), a plurality of laser element bases 20 (20-1, 20-2, and 20-3) which respectively have main surfaces 21 (21-1, 21-2, and 21-3) and bonding surfaces 22 (22-1, 22-2, and 22-3) and in which the plurality of laser elements 30 (30-1, 30-2, and 30-3) are respectively installed on the main surfaces 21 (21-1, 21-2, and 21-3), an optical waveguiding substrate 40 which has a main surface 41 and a bonding surface 42 and in which an optical waveguiding layer 50 is provided with optical waveguides 51 for waveguiding laser light emitted from the plurality of laser elements 30 (30-1, 30-2, and 30-3) on the main surface 41, a plurality of spacer layers 72 (72-1, 72-2, and 72-3) which are disposed away from each other at positions respectively corresponding to the plurality of laser element bases 20 (20-1, 20-2, and 20-3) on the bonding surface 42 of the optical waveguiding substrate 40, and a plurality of metal laminate films 70 (70-1, 70-2, and 70-3) which bond the bonding surfaces 22 (22-1, 22-2, and 22-3) of the plurality of laser element bases 20 (20-1, 20-2, and 20-3) and the bonding surface 42 of the optical waveguiding substrate 40. The plurality of metal laminate films 70 (70-1, 70-2, and 70-3) are respectively disposed on the plurality of spacer layers 72 (72-1, 72-2, and 72-3) and have a plurality of first metal films 73 (73-1, 73-2, and 73-3) and second metal films 74 (74-1, 74-2, and 74-3) that are disposed on the bonding surfaces 22 (22-1, 22-2, and 22-3) of the plurality of laser element bases 20 (20-1, 20-2, and 20-3) and made of metals capable of being eutectic with metals constituting the first metal films 73 (73-1, 73-2, and 73-3).

### <Laser Element and Laser Element Base>

Various kinds of laser elements can be used as the laser elements 30. For example, commercially available laser diodes (which may hereinafter be referred to as LDs) of red light, green light, blue light, near infrared light, ultraviolet light, and the like can be used. Light having a peak wavelength of 630 nm to 830 nm can be used as red light (R), light having a peak wavelength of 500 nm to 550 nm can be used as green light (G), and light having a peak wavelength of 380 nm to 500 nm can be used as blue light (B). In addition, light having a peak wavelength of 830 nm to 2,000 nm can be used as near infrared light.

In the laser assembly 100 shown in FIG. 1, for the sake of convenience, the laser elements 30-1, 30-2, and 30-3 will be described as an LD emitting red light, an LD emitting green light, and an LD emitting blue light, respectively. For example, the laser elements 30-1, 30-2, and 30-3 can be respectively mounted as bare chips (unpackaged chips) on the individual laser element bases 20-1, 20-2, and 20-3. The number of laser elements shown in FIG. 1 is three, but this is merely an example, and an arbitrary number can be employed for the plurality of laser elements.

For example, the laser element bases 20-1, 20-2, and 20-3 are constituted using aluminum nitride (AIN), aluminum oxide (Al₂O₃), or silicon (Si).

Metal films 75 and 76 are provided between the laser element bases 20 and the laser elements 30 (refer to FIGS. 2). The laser element bases 20 and the laser elements 30 are connected with the metal films 75 and 76 therebetween. Regarding a method for forming the metal films 75 and 76, a known method can be utilized without any particular limitation, and a known technique such as sputtering, vapor deposition, or metal paste coating can be utilized. For example, the metal films 75 and 76 may contain one or a plurality of metals selected from the group consisting of gold (Au), platinum (Pt), silver (Ag), lead (Pb), indium (In), nickel (Ni), titanium (Ti), tantalum (Ta), tungsten (W), a gold (Au)—tin (Sn) alloy, a tin (Sn)—silver (Ag)—copper (Cu)-based solder alloy (SAC), SnCu, InBi, SnPdAg, SnBiIn, and PbBiIn, or may be constituted using one or a plurality of metals selected from this group.

<Optical Waveguiding Layer and Optical Waveguiding Substrate>

The optical waveguiding layer 50 has at least optical waveguides for waveguiding laser light emitted from the laser elements. There are no particular limitations on this optical waveguiding layer, and a known constitution can be employed, for example. Hereinafter, an example of the optical waveguiding layer will be described.

The optical waveguiding layer 50 is a layer which performs functions of a planar lightwave circuit (PLC). In addition, optical waveguides 51-1, 51-2, and 51-3 correspond to cores in optical fibers.

The optical waveguiding layer 50 is formed on the optical waveguiding substrate 40, and as described above, the laser elements 30 are placed on the placed laser element bases 20.

The optical waveguiding substrate 40 and the laser element bases 20 are integrated by eutectic bonding. Due to this eutectic bonding, optical axes can be accurately disposed, and miniaturization is realized.

For example, the optical waveguiding substrate 40 is constituted using silicon (Si). The optical waveguiding layer 50 is produced on the main surface 41 such that it is integrated with the optical waveguiding substrate 40 through a known semiconductor process including photolithography and dry etching used when fine structures such as integrated circuits are formed. As shown in FIG. 1, the optical waveguiding layer 50 is provided with the optical waveguides (cores) 51-1, 51-2, and 51-3 of which the number is the same as that of the laser elements 30-1, 30-2, and 30-3, and a cladding 52 which surrounds the optical waveguides 51-1, 51-2, and 51-3. There are no particular limitations on the thickness of the cladding 52 and the dimensions of the optical waveguides 51-1, 51-2, and 51-3 in the width direction. For example, the optical waveguides 51-1, 51-2, and 51-3 having dimensions of approximately several microns in the width direction are arranged in the cladding 52 having a thickness of approximately 50 μm.

For example, the optical waveguides 51-1, 51-2, and 51-3 and the cladding 52 are constituted using a glass material (for example, quartz glass). In this case, the optical waveguiding layer 50 may be referred to as a quartz-based PLC. Refractive indices of the optical waveguides 51-1, 51-2, and 51-3 are higher than the refractive index of the cladding 52 by a predetermined value. Due to this, light which has been incident on each of the optical waveguides 51-1, 51-2, and 51-3 is totally reflected at an interface between each optical waveguide and the cladding 52 and is propagated through each optical waveguide. For example, the optical waveguides 51-1, 51-2, and 51-3 are doped with impurities such as germanium (Ge) in an amount corresponding to the predetermined value described above.

As shown in FIG. 1, the optical waveguides 51-1, 51-2, and 51-3 are gathered into one waveguide before reaching an emission surface 64 of the optical waveguiding layer 50. That is, the optical waveguides 51-1, 51-2, and 51-3 sequentially merge together as they go forward in an x direction and merge into one optical waveguide 51-4. In order to prevent occurrence of leakage of light from the optical waveguides 51-1, 51-2, and 51-3, it is preferable that each of the optical waveguides 51-1, 51-2, and 51-3 be connected to the optical waveguide 51-4 with a radius of curvature equal to or greater than a predetermined radius of curvature.

Due to eutectic bonding between the optical waveguiding substrate 40 and the laser element bases 20, in a state in which the optical axes are accurately aligned such that the center of an incidence port in each of the optical waveguides 51-1, 51-2, and 51-3 of the optical waveguiding layer 50 almost matches the optical axis of emission light from each of the corresponding laser elements 30-1, 30-2, and 30-3, each optical waveguide and each corresponding laser element are disposed facing each other.

As shown in FIG. 2, an incidence surface 50A of the optical waveguiding layer 50 is disposed in a manner of facing an emission surface 30A (30-1A) of the laser element 30. Specifically, an emission port 31-1 of the laser element 30-1 faces an incidence port 51-1A of the waveguide 51-1. In the x direction and a z direction, the optical axis of red light emitted from the laser element 30-1 substantially overlaps the center of the incidence port 51-1A. Similarly, the emission port of the laser element 30-2 faces the incidence port of the waveguide 51-2. In the x direction and the z direction, the optical axis of green light emitted from the laser element 30-2 substantially overlaps the center of the incidence port. The emission port of the laser element 30-3 faces the incidence port of the waveguide 51-3. In the x direction and the z direction, the optical axis of blue light emitted from the laser element 30-3 substantially overlaps the center of the incidence port.

As shown in FIG. 1, red light, green light, and blue light emitted from the laser elements 30-1, 30-2, and 30-3 are respectively incident on the optical waveguides 51-1, 51-2, and 51-3 and then are propagated through the respective optical waveguides. Red light and green light which have been propagated through the optical waveguides 51-3 and 51-2 are multiplexed at a merging position 57-1. The multiplexed red light and green light, and blue light which has been propagated through the 51-3 merge together at a merging position 57-2. RGB light which has been multiplexed at the merging position 57-2 is propagated through the optical waveguide 51-4, reaches the emission surface 64, and is emitted from the emission surface 64.

### <Bonding Portion Between Laser Element Bases and Optical Waveguiding Substrate>

The plurality of individual laser element bases 20-1, 20-2, and 20-3 and the optical waveguiding substrate 40 are bonded with the plurality of metal laminate films 70 (70-1, 70-2, and 70-3) therebetween.

The plurality of metal laminate films 70 (70-1, 70-2, and 70-3) are constituted of the plurality of first metal films 73 (73-1, 73-2, and 73-3) and the plurality of second metal films 74 (74-1, 74-2, and 74-3). The metal laminate films 70 are separated electrically and spatially between adjacent laser element bases.

Before bonding, as shown in FIG. 3B, the plurality of first metal films 73 (73-1, 73-2, and 73-3) are disposed on the plurality of spacer layers 72 (72-1, 72-2, and 72-3) which are installed away from each other on the bonding surface 42 of the optical waveguiding substrate 40, and as shown in FIG. 3A, the plurality of second metal films 74 (74-1, 74-2, and 74-3) are respectively disposed on the bonding surfaces 22-1, 22-2, and 22-3 of the plurality of laser element bases 20 (20-1, 20-2, and 20-3).

If parts where the laser element bases and the optical waveguiding substrate are bonded are referred to as bonding portions, the bonding portions are constituted of the metal laminate films 70 and the spacer layers 72, and bonding is realized by eutectic bonding between first metal films 73 and second metal films 74.

Preferable eutectic bonding includes Au—Sn bonding. Regarding the materials of the first metal films 73 and the second metal films 74, a combination in which Au—Sn bonding is formed at the time of bonding is preferable.

In eutectic bonding formed between the first metal films 73 and the second metal films 74, the degree of eutectic (alloying) may vary depending on the conditions, and there may be a structure in which a relatively many parts of one of or both the first metal films 73 and the second metal films 74 remain non-eutectic or a structure in which the first metal films 73 and the second metal films 74 are entirely alloyed and an eutectic layer is formed.

A metal laminate films 70 are not films which are continuously subjected to film formation but are separate films disposed away from each other. Since they are separate films, occurrence of capacitive coupling is curbed, and crosstalk is curbed.

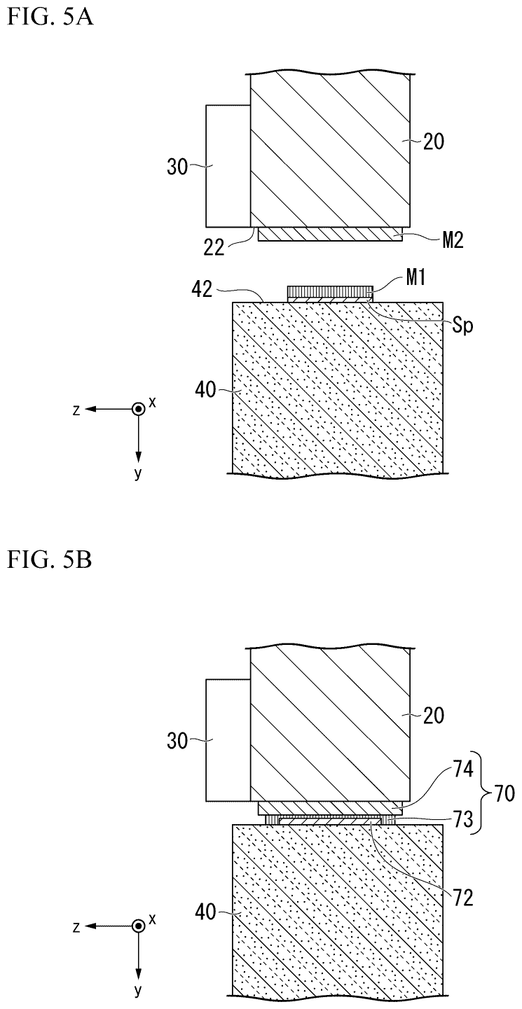

FIGS. 5A and 5B are schematic views showing a step of bonding the laser element bases and the optical waveguiding substrate. FIG. 5A shows a state before bonding, and FIG. 5B shows a state after bonding.

In bonding between the laser element bases 20 and the optical waveguiding substrate 40, as shown in FIG. 5A, metal films M1, spacer layers Sp, and metal films M2 constituting the bonding portions are subjected to film formation in advance. That is, the spacer layers Sp are formed on the bonding surface 42 of the optical waveguiding substrate 40, and subsequently the metal films M1 are formed on the spacer layers Sp. On the other hand, the metal films M2 are subjected to film formation on the bonding surfaces 22 (22-1, 22-2, and 22-3) of the laser element bases 20-1, 20-2, and 20-3. The metal films M1, the spacer layers Sp, and the metal films M2 become the first metal films 73, the spacer layers 72, and the second metal films 74 after bonding. However, since their forms may change via melting and bonding before and after bonding (although the spacer layers usually remain almost unchanged), different reference signs are applied.

Next, the bonding portions are heated by a known method such as laser irradiation, the metal films M1 are caused to melt, and the laser element bases and the optical waveguiding substrate are bonded by pressing both or one of them by eutectic bonding. The metal films M1 and the metal films M2 are a combination of metals which can be used for eutectic bonding. The bonding portions after bonding are constituted of the spacer layers 72, the first metal films 73, and the second metal films 74. Since the bonding portions are realized by metal films which have once melted and which then form coupling and are solidified, it is difficult to accurately show their form in the diagrams. However, description will be given using diagrams such that the characteristics thereof can be ascertained as much as possible.

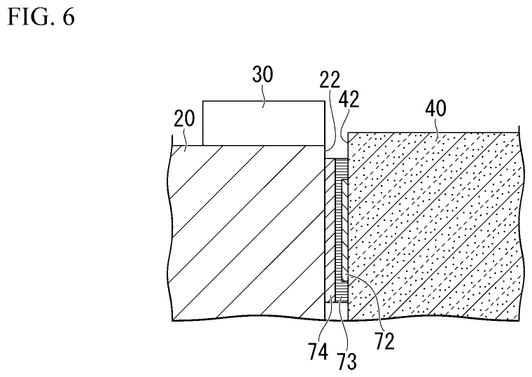

FIG. 5B illustrates an example of a characteristic bonding portion. After the metal films M1 disposed on the spacer layers Sp have melted, the laser element bases 20 press (pressurize) them so that a part of them spreads on the bonding surface 42 around the spacer layers Sp and forms the first metal films 73. In the example shown in FIG. 5B, the second metal films 74 are formed to have an area larger than the areas of the first metal films 73 which have spread and been formed. That is, when seen in a direction (y direction) in which the bonding surface 42 and the bonding surfaces 22 are connected, the second metal films 74 are formed to have an area larger than the areas of the first metal films 73 such that the first metal films 73 are covered. Another example of a characteristic form will be described using FIG. 6.

In the laser assembly 100 of the present embodiment, since the spacer layers 72 are provided on the bonding surface 42 of the optical waveguiding substrate 40, even if they are pressed at the time of a bonding step, a gap S (refer to FIGS. 2) between the laser element bases 20 and the optical waveguiding substrate 40 can maintain a predetermined size. When all the metal films M1 melt at the time of the bonding step and the like, the gap S becomes extremely small. In this case, the melted metal films M1 pushed out to the outside from a space between the laser element bases 20 and the optical waveguiding substrate 40. In contrast, since the laser assembly 100 of the present embodiment includes the spacer layers 72, the gap S is maintained to be equal to or larger than the thicknesses of the spacer layers 72. As a result, a situation in which the melted metal films M1 are pushed out to the outside from the space between the laser element bases 20 and the optical waveguiding substrate 40 is curbed.

A seed layer may be formed when the metal films M1 and M2 are subjected to film formation on the respective bonding surfaces. Since this seed layer is extremely thinner than the thicknesses of the metal films M1 and M2, if the optical waveguiding substrate 40 and the laser element bases 20 are heated and pressed, the clearance between the optical waveguiding substrate 40 and the laser element bases 20 cannot be maintained, and the melted metal films M1 are pushed out from between them.

The gap S between the laser element bases 20 and the optical waveguiding substrate 40 depends on the thicknesses of the spacer layers and the amounts of the metal films M1 and M2, and a specific example of the size is approximately 0.2 to 1.2 μm. The volume of the void between the laser element bases 20 and the optical waveguiding substrate 40 can be determined on the basis of the volume of the melted metal.

The thicknesses of the spacer layers 72 can be determined in accordance with the volumes of the metal films M1 and M2 required to prevent the metal films M1 from overflowing from the space between the laser element bases 20 and the optical waveguiding substrate 40 when they melt and to achieve a desired strength of eutectic bonding between the laser element bases 20 and the optical waveguiding substrate 40.

Examples of the material of the spacer layers 72 include oxides such as alumina (Al₂O₃), titanium oxide (TiOx), tantalum oxide (TaOx), and silicon oxide (SiOx), and metals such as Ti and Ta.

A rare metal such as Ti or Ta is used as the material of a so-called seed film. Therefore, when the spacer layers 72 are made of a rare metal such as Ti or Ta, the same material as that of the seed film is used as the material thereof. However, a seed film is usually used with a thickness of approximately several tens of nm. In contrast, in the case of the spacer layers 72, in order to sufficiently secure the gap S, the thickness is preferably 0.1 μm or larger and is more preferably 0.2 μm or larger. The metal films M1 and M2 can be stored inside this space (gap) by securing the gap S in which a space (gap) can be formed to be able to maintain a condition that the volume of the space (gap) between the laser element bases 20 and the optical waveguiding substrate 40 is larger than the volumes of the metal films M1 which melt at the time of bonding.

In addition, in this case, from the viewpoint of material costs, the upper limit for the spacer layers 72 is approximately 0.4 μm.

In contrast, when the spacer layers 72 are made of an oxide such as alumina, for the purpose of providing the spacer layers 72, similar to the case of being made of a rare metal, the thicknesses of the spacer layers 72 are preferably 0.1 μm or larger and are more preferably 0.2 μm or larger. On the other hand, from the viewpoint of material costs, the upper limit can be relaxed. However, since there is concern that deformation may occur due to excessive internal stress, the upper limit for the thicknesses of the spacer layers 72 is preferably 1 μm, for example. It is preferable to select a material having small internal stress.

At least a part the first metal films 73 is disposed on the spacer layers 72. The first metal films 73-1, 73-2, and 73-3 are disposed away from each other.

The first metal films 73-1, 73-2, and 73-3 having the same size as the spacer layers can be laminated on the respective spacer layers 72-1, 72-2, and 72-3 using a photomask, which has been used at the time of film formation of the spacer layers 72 (72-1, 72-2, and 72-3), at the time of film formation of the first metal films 73 (73-1, 73-2, and 73-3) without any change. In addition, the first metal films 73 having a smaller size than the spacer layers 72 can be laminated using a photomask, which has a smaller hole size than the photomask used at the time of film formation of the spacer layers 72 (72-1, 72-2, and 72-3), at the time of film formation of the first metal films 73 (73-1, 73-2, and 73-3).

At the time of bonding between the laser element bases and the optical waveguiding substrate, in order to cause the first metal films 73 to melt, depending on the difference between the sizes of the first metal films 73 and the spacer layers 72, a part of the first metal films 73 is disposed not only on the spacer layers 72 but also on the bonding surface 42 around the spacer layers 72 (refer to FIGS. 5B and 6).

It is preferable that the first metal films 73 be made of Sn or an alloy containing Sn such as Sn—Ag—Cu (SAC).

The thicknesses of the first metal films 73 to be subjected to film formation in advance on the spacer layers 72 before being bonded to the laser element bases can be approximately 0.2 to 0.6 μm, for example.

When the first metal films 73 are subjected to film formation on the spacer layers 72, a seed film constituted of a film of a metal selected from the group consisting of Ta, Ti, Ni, Ta/Pt, Ti/Pt, and Ni/Pt may be used. Here, a metal film of Ta/Pt, Ti/Pt, or Ni/Pt is a two-layer film constituted of a Ta film, a Ti film, or a Ni film and a Pt film. A Pt film of the two-layer film is disposed on a side which directly comes into contact with the first metal films 73. It is possible to expect that the bonding strength between the first metal films 73 and the seed film will increase by inserting a Pt film. For example, from the viewpoint of preventing the metal of the first metal films 73 from flowing out through the gap at the time of bonding, it is preferable that the first metal films 73 be formed to have a smaller area. However, if the first metal films 73 become smaller, the bonding strength with respect to the seed film becomes weaker. It is possible to expect that degradation in bonding strength will be curbed by inserting a Pt film.

Since a Sn film or an alloy film containing Sn does not form an eutectic alloy with a Ta film, a Ti film, or a Ni film, the interface between a Sn film or an alloy film containing Sn and a Ta film, a Ti film, or a Ni film can be identified in an electron microscopy image. However, peeling occurs at this interface if peeling-off is performed. On the other hand, since a Sn film or an alloy film containing Sn forms an eutectic alloy with a Pt film, the interface between a Sn film or an alloy film containing Sn and a Pt film may be undistinguishable, and it may not be able to be identified in an electron microscopy image.

The second metal films 74 are preferably made of a metal which can form an eutectic alloy with Sn. For example, they are preferably made of a metal selected from the group consisting of Au, Si, Al, Ni, Zn, Pt, and alloys of these. It is most preferable that the second metal films 74 be a Au film forming a firm eutectic alloy with Sn.

The thicknesses of the second metal films 74 to be subjected to film formation in advance on the bonding surfaces 22 of the laser element bases 20 before being bonded to the optical waveguiding substrate 40 can be approximately 0.2 to 1.0 μm, for example.

The second metal films 74 are formed to have a larger area than the spacer layers 72, and the second metal films 74 are formed such that the spacer layers 72 are covered when seen in a direction orthogonal to the films.

The second metal films 74 are formed to have a larger area than the first metal films 73 and are preferably formed such that the first metal films 73 are covered when seen in a direction orthogonal to the films.

Each of the films is formed before the laser element bases and the optical waveguiding substrate are bonded. However, at this time, the second metal films 74 need only be formed to have a larger area than the spacer layers 72 and be formed to have a larger area than the first metal films 73.

When the second metal films 74 are subjected to film formation on the bonding surfaces 22 of the laser element bases 20, a seed film constituted of a film of a metal selected from the group consisting of Ta, Ti, Ta/Pt, and Ti/Pt may be used. Here, a metal film of Ta/Pt or Ti/Pt is a two-layer film constituted of a Ta film or a Ti film and a Pt film. A Pt film of the two-layer film is disposed on a side which directly comes into contact with the second metal films 74. It is possible to expect that the bonding strength between the second metal films 74 and the seed film will increase by inserting a Pt film.

FIG. 6 shows an example of a film structure of the metal laminate films 70 and the spacer layers 72 constituting the bonding portions having characteristics different from those shown in FIG. 5B.

The example shown in FIG. 6 is similar to that in FIG. 5B in that after the metal films M1 disposed on the spacer layers Sp have melted, the laser element bases 20 press them so that a part of them spreads on the bonding surface 42 around the spacer layers Sp and forms the first metal films 73. However, this example differs in that the second metal films 74 are formed to have an area which is approximately the same as the areas of the first metal films 73.

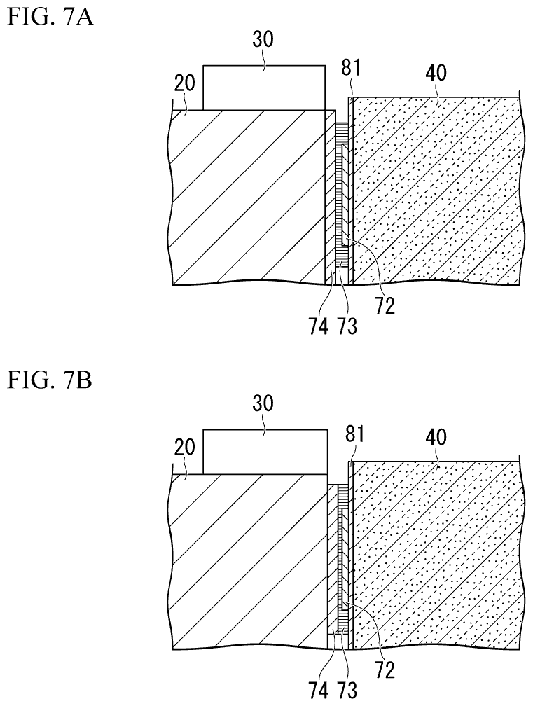

FIGS. 7A and 7B show a constitution provided with an antireflection film 81 on the bonding surface 42 of the optical waveguiding substrate 40. FIGS. 7A and 7B respectively correspond to FIGS. 5B and 6. In the case of this constitution, the spacer layers 72 are formed on the antireflection film 81.

The antireflection film 81 is a film for preventing incident light or emission light on the optical waveguiding layer 50 from being reflected in a direction opposite to the direction in which the light enters each surface from the incidence surface 50A or the emission surface 64 and increasing the transmittance of incident light or emission light. For example, the antireflection film 81 is a multiplayer film formed by alternately laminating a plurality of kinds of dielectrics with predetermined thicknesses corresponding to wavelengths of red light, green light, and blue light (incident light). Examples of the dielectrics include titanium oxide (TiO2), tantalum oxide (Ta₂O₅), silicon oxide (SiO₂), and aluminum oxide (Al₂O₃).

The emission surfaces 30A of the laser elements 30 and the incidence surface 50A of the optical waveguiding layer 50 are disposed with a predetermined gap therebetween. The incidence surface 50A faces the emission surfaces 30A, and there is a clearance between the emission surfaces 30A and the incidence surface 50A in the x direction. In consideration of the laser assembly 100 being used in XR glasses, the amount of light required in XR glasses, and the like, the size of the clearance in the y direction is larger than 0 μm and equal to or smaller than 5 μm, for example.

### [Laser Module]

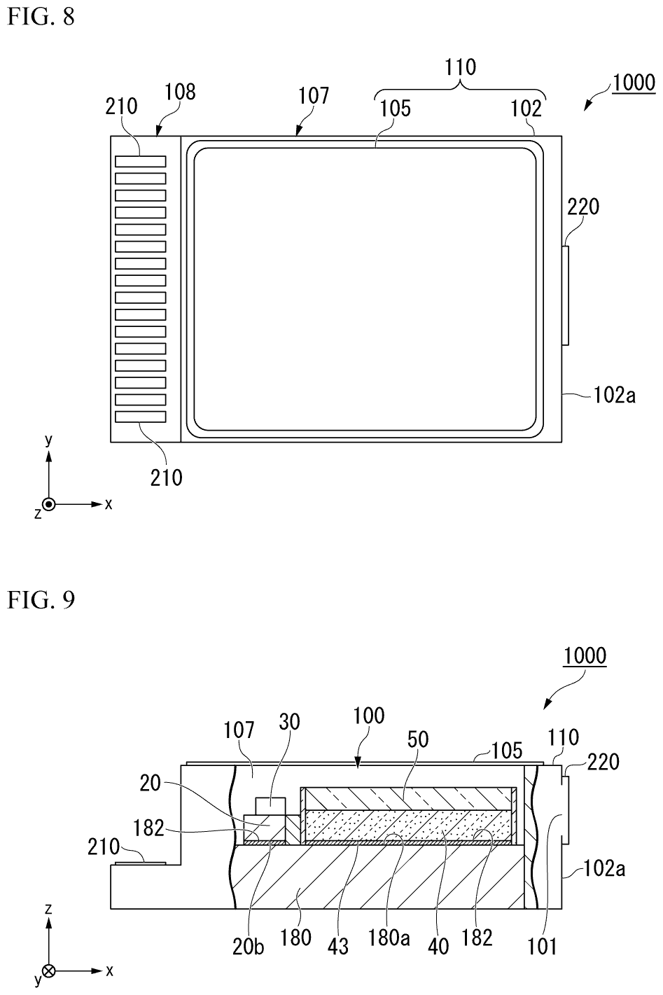

FIG. 8 is a schematic plan view of a laser module of the present embodiment. FIG. 9 is a view showing a cross section of the laser assembly disposed inside the laser module shown in FIG. 8 of which a part is cut along an X-Z plane.

In a laser module 1000 shown in FIG. 8, the laser assembly 100 according to the foregoing embodiment is accommodated inside a package 110 and is installed on an upper surface 180a of a base 180.

In the laser assembly 100 accommodated inside the package 110, it is preferable that bottom surfaces 20b of the laser element bases 20 and a bottom surface 43 of the optical waveguiding substrate 40 be bonded to each other so as to be positioned on substantially the same plane. In the laser assembly 100, since the laser element bases 20 and the optical waveguiding substrate 40 are bonded by eutectic bonding of metals, compared to a constitution in which they are bonded using an adhesive, occurrence of positional deviation during a heating step is remarkably curbed.

The said term “substantially the same plane” allows for a slight deviation between the bottom surfaces 20b of the laser element bases 20 and the bottom surface 43 of the optical waveguiding substrate 40. Specifically, a deviation within a range of 20 μm or smaller is allowed for with respect to the thickness of the optical waveguiding substrate 40 in the z direction. However, it is better to have a smaller deviation, which is more preferably 10 μm or smaller and is even more preferably 5 μm or smaller.

When the bottom surfaces 20b of the laser element bases 20 and the bottom surface 43 of the optical waveguiding substrate 40 are bonded to each other so as to be positioned on substantially the same plane, heat generated during operation of the laser elements 30 can be efficiently dissipated on both the bottom surfaces 20b of the laser element bases 20 and the bottom surface 43 of the optical waveguiding substrate 40.

In addition, when the bottom surfaces 20b of the laser element bases 20 and the bottom surface 43 of the optical waveguiding substrate 40 are bonded to each other so as to be positioned on substantially the same plane, since both the bottom surfaces 20b of the laser element bases 20 and the bottom surface 43 of the optical waveguiding substrate 40 can be bonded on one plane on the upper surface 180a of the base 180, a high bonding strength can be maintained so that the laser assembly 100 having an excellent shock resistance can be realized.

In this manner, in a constitution in which the bottom surfaces 20b of the laser element bases 20 and the bottom surface 43 of the optical waveguiding substrate 40 are bonded to each other so as to be positioned on substantially the same plane, the heat dissipation properties and the shock resistance can be improved.

Known constituent elements other than the laser assembly according to the foregoing embodiment may be provided inside the package 110. For example, a light receiver (photodetector: PD) can be accommodated therein.

By providing a PD, it is possible to check fluctuations in light output of the laser elements by observing currents flowing through the PD. In addition, drive currents of the laser elements can be controlled such that outputs become constant by monitoring the currents flowing through the PD.

The package 110 includes a main body 102 having a cavity structure, and a cover 105 covering the main body 102.

The main body 102 has a bottom portion on which members accommodated therein are placed, and a side wall portion 102a which is disposed so as to enclose these members from the side.

A light transmitting window 101 allowing laser light L emitted from the laser elements 30 to be optically transmitted therethrough is formed in the side wall portion 102a which is disposed in a direction in which the laser light is emitted.

The light transmitting window (opening) 101 is formed in the side wall portion 102a, of side wall portions of an accommodation portion 107, in the vicinity of an emission portion for the laser light L emitted from the laser module 1000. The opening 101 is formed with a position intersecting the optical axis of the laser light emitted in the side wall portion 102a as substantially the center. The opening 101 is covered by a glass plate 220 from the outside of the side wall portion 102a with no clearance therebetween. Namely, the accommodation portion 107 is hermetically sealed by the glass plate 220 in addition to the cover 105. The glass plate 220 is used for hermetic sealing, but the material is not limited to a glass plate as along as laser light can be transmitted therethrough. An antireflection film (not shown) may be provided on both plate surfaces of the glass plate 220.

An electrode portion 108 is disposed on a side in front of the accommodation portion 107 in the x direction, that is, a rear side in the x direction. An upper surface of the electrode portion 108 is positioned below an upper surface of the accommodation portion 107. A bottom surface of the electrode portion 108 is positioned at substantially the same height as a bottom surface of the accommodation portion 107. A plurality of external electrode pads 210 are provided on the upper surface of the electrode portion 108 with gaps therebetween in the y direction.

The bottom surfaces 20b of the laser element bases 20 and the bottom surface 43 of the optical waveguiding substrate 40 need only be bonded with an adhesive layer 182 therebetween with respect to the upper surface 180a (one inner surface) of the base 180. A material in which a filler is mixed into a resin in order to increase the heat conductivity is used for this adhesive layer 182. Examples of the resin constituting the adhesive layer 182 include an epoxy resin. In addition, a copper powder, an aluminum powder, an alumina powder, or the like can be used as a filler improving the heat conductivity of the resin.

In order to maintain the heat conductivity in a certain level or higher, such an adhesive layer 182 preferably has a heat conductivity of 0.5 W/m·K or higher, more preferably has a heat conductivity of 1 W/m·K or higher, and even more preferably has a heat conductivity of 4 W/m·K or higher.

In this manner, by bonding both the laser element bases 20 and the optical waveguiding substrate 40 of the laser assembly to the upper surface 180a of the base 180 inside the package 110, heat generated during operation of the laser elements 30 can be efficiently dissipated toward the base 180 from both the bottom surfaces 20b of the laser element bases 20 and the bottom surface 43 of the optical waveguiding substrate 40. In addition, moreover, by bonding both the bottom surfaces 20b of the laser element bases 20 and the bottom surface 43 of the optical waveguiding substrate 40 using an adhesive layer made of a resin into which a filler is mixed, heat can be efficiently propagated toward the base 180 from both the bottom surfaces 20b of the laser element bases 20 and the bottom surface 43 of the optical waveguiding substrate 40.

Next, a case in which the optical waveguiding layer included in the laser assembly is constituted of a lithium niobate film (LiNbO₃) will be described. Regarding the quartz-based PLC described earlier, in this case, the optical waveguiding layer may be referred to as a LN-based PLC.

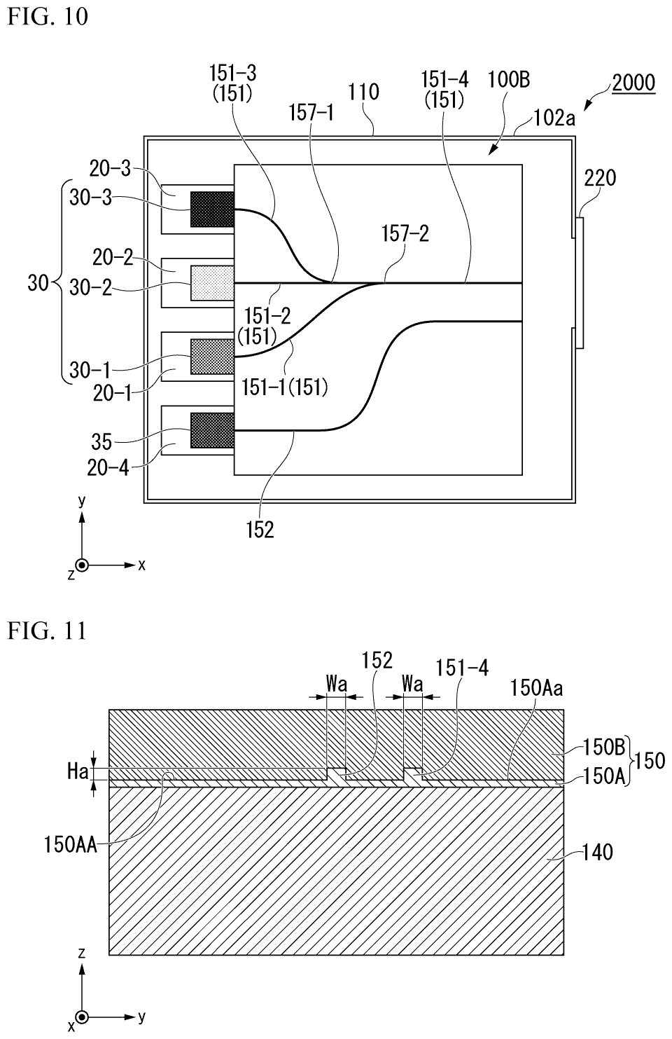

FIG. 10 shows a schematic plan view of a state in which a cover is removed from a laser module accommodating a laser assembly that has the optical waveguiding substrate including an optical waveguiding layer constituted of a lithium niobate film. FIG. 11 is a schematic plan view of the laser assembly shown in FIG. 10 seen from the emission surface of the laser element.

The same reference signs are applied to members common to those of the laser assembly and the laser module described above, and description thereof may be omitted. FIG. 10 shows an example in which the laser assembly has a near infrared laser element in addition to the RGB laser elements as the laser elements. Since a near infrared laser is invisible, it can be used in eye tracking. The laser assembly described above may also be constituted to include a near infrared laser element.

In a laser module 2000 shown in FIG. 10, a laser assembly 100B, including the laser element bases 20 (20-1, 20-2, and 20-3) on which the laser elements 30 (30-1, 30-2, and 30-3) and the laser elements 30 (30-1, 30-2, and 30-3) are respectively placed, a near infrared laser element 35 and a laser element base 20-4 on which the near infrared laser element 35 is placed, an optical waveguiding substrate 140 in which a LN-based PLC 150 is formed on a main surface thereof, and bonding portions in which the bonding surfaces of the laser element bases 20 and the laser element base 20-4 and the bonding surface of the optical waveguiding substrate 140 are constituted of spacer layers and metal laminate films subjected to eutectic bonding, is accommodated inside the package 110.

Similar to the laser elements 30, the near infrared laser element 35 is mounted on the laser element base 20-4, and the LN-based PLC 150 is formed on the optical waveguiding substrate 140.

Inside the package 110, the laser module 2000 includes optical waveguides 151 (151-1, 151-2, and 151-3) for waveguiding laser light emitted from the laser elements 30, and the LN-based PLC 150 including an optical waveguide 152 for waveguiding near infrared laser light emitted from the near infrared laser element 35.

In the laser module 2000 as well, the optical waveguiding substrate 140 on which the LN-based PLC 150 is formed, and the laser element bases 20 on which the laser elements 30 are placed and the laser element base 20-4 on which the near infrared laser element 35 is placed are integrated by eutectic bonding.

Due to this eutectic bonding, optical axes can be accurately disposed, and miniaturization is realized.

Examples of the optical waveguiding substrate 140 include a sapphire substrate, a Si substrate, and a thermally oxidized silicon substrate.

When the optical waveguides 151 and the optical waveguide 152 are form using a lithium niobate (LiNbO₃) film, there are no particular limitations on the material as along as it has a lower refractive index than a lithium niobate film. However, it is preferable to use a sapphire single-crystal substrate or a silicon single-crystal substrate as a substrate in which a single-crystal lithium niobate film can be formed as an epitaxial film. The crystal orientation of the single-crystal substrate is not particularly limited. However, for example, since a lithium niobate film with a c-axis orientation has three-fold symmetry, it is also desirable for the single-crystal substrate (base) to have the same symmetry. In the case of a sapphire single-crystal substrate, it is preferable to use a substrate having a c-plane, and in the case of a silicon single-crystal substrate, it is preferable to use a substrate having a (111) plane.

In the laser module 2000, the optical waveguiding layer (LN-based PLC) 150 has an optical waveguide film 150A which has the optical waveguides 151 and the optical waveguide 152, and a waveguide cladding film 150B which is formed on the optical waveguide film 150A such that the optical waveguides 151 and the optical waveguide 152 are covered. The waveguide cladding film 150B has a lower refractive index than the optical waveguide film 150A. For example, the waveguide cladding film 150B is made of SiInO, SiO₂, Al₂O₃, MgF₂, La₂O₃, ZnO, HfO₂, MgO, Y₂O₃, CaF₂, In₂O₃ or a mixture of these.

For example, the lithium niobate film (optical waveguide film 150A) is a lithium niobate film with the c-axis orientation. For example, the lithium niobate film is an epitaxial film which is epitaxially grown on the optical waveguiding substrate 140. An epitaxial film denotes a single-crystal film in which the crystal orientation is aligned due to a base substrate. An epitaxial film is a film which has a single crystal orientation in the z direction and a direction within the xy plane and in which crystals have aligned orientations in all the x axis direction, the y axis direction, and the z axis direction. Whether a film formed on the optical waveguiding substrate 140 is an epitaxial film can be proved, for example, by confirming the peak intensity and the pole at an orientation position in 2θ-θX ray diffraction.

The composition of lithium niobate is LiₓNbA_{y}O_{z}. A is an element other than Li, Nb, and O. The element x is 0.5 to 1.2 and is preferably 0.9 to 1.05. The element y is 0 to 0.5. The element z is 1.5 to 4.0 and is preferably 2.5 to 3.5. For example, the element of A is K, Na, Rb, Cs, Be, Mg, Ca, Sr, Ba, Ti, Zr, Hf, V, Cr, Mo, W, Fe, Co, Ni, Zn, Sc, or Ce, and two or more kinds of these elements may be combined.

The thickness of the lithium niobate film is 2 μm or smaller, for example. The thickness of the lithium niobate film denotes a thickness of a part other than a ridge portion. If the lithium niobate film has a large thickness, there is concern that crystallinity may be degraded.

In addition, the thickness of the lithium niobate film is approximately 1/10 or larger than the wavelength of light used, for example. If the lithium niobate film has a small thickness, confinement of light becomes weak so that light leaks in the optical waveguiding substrate 140 or the waveguide cladding film 150B.

The optical waveguides 151 and the optical waveguide 152 are light passages in which light is internally propagated. The optical waveguides 151 and the optical waveguide 152 are ridges protruding from a first surface 150AA of a slab layer 150Aa of the optical waveguide film 150A. Hereinafter, the optical waveguide 151-1, the optical waveguide 151-2, the optical waveguide 151-3, and the optical waveguide 152 may be referred to as the ridge 151-1, the ridge 151-2, the ridge 151-3, and the ridge 152, respectively. The first surface 150AA is an upper surface in a part (slab layer 150Aa) other than the ridge portions of the optical waveguide film 150A. The optical waveguide film 150A is constituted of the ridges 151-1, 151-2, 151-3, and 152 and the slab layer 150Aa.

A ridge 151-4 and the ridge 152 shown in FIG. 11 have a rectangular cross-sectional shape, but they need only have a shape capable of waveguiding light. For example, they may have a trapezoidal shape, a triangular shape, a semicircular shape, or the like. It is preferable that a width Wa in the y direction be 0.3 μm to 5.0 μm, and it is preferable that the heights of the ridges (a protrusion height Ha from the first surface 150AA) be 0.1 μm to 1.0 μm, for example.

As shown in FIG. 10, the optical waveguide 151-1, the optical waveguide 151-2, and the optical waveguide 151-3 are gathered into one waveguide before reaching the emission surface of the optical waveguiding layer 150. That is, the optical waveguide 151-1, the optical waveguide 151-2, and the optical waveguide 151-3 sequentially merge together as they go forward in the x direction and merge into one optical waveguide 151-4. In order to prevent occurrence of leakage of light from the optical waveguide 151-1, the optical waveguide 151-2, and the optical waveguide 151-3, it is preferable that each of the optical waveguide 151-1, the optical waveguide 151-2, and the optical waveguide 151-3 be connected to the optical waveguide 151-4 with a radius of curvature equal to or greater than a predetermined radius of curvature.

As shown in FIG. 10, red light, green light, and blue light emitted from the laser elements 30-1, 30-2, and 30-3 are respectively incident on the ridges 151-1, 151-2, and 151-3 and then are propagated through the respective ridges. Red light and green light which have been propagated through the ridge 151-3 and 151-2 are multiplexed at a predetermined merging position 157-1 behind a merging position 157-2 in the x direction. The multiplexed red light and green light, and blue light which has been propagated through the 151-2 are multiplexed at the merging position 57-2. RGB light which has been multiplexed at the merging position 57-2 is propagated through the ridge 151-4, reaches the emission surface, and is emitted from the emission surface.

In addition, near infrared light emitted from the laser element 35 is propagated through the ridge 152, reaches the emission surface, and is emitted from the emission surface.

Each of the optical waveguides 151-1, 151-2, 151-3, and 152 included in the LN-based optical waveguiding layer 150 may be a Mach-Zehnder-type optical waveguide. In this case, a known Mach-Zehnder-type optical modulation portion such as an electrode (not shown) for applying an electric field to the optical waveguides is provided.

### [XR Glasses]

In XR glasses according to the present embodiment, the laser module according to the foregoing embodiment is mounted on a glass. The XR glasses (glasses) are a glasses-type terminal, and XR is a generic term of virtual reality (VR), augmented reality (AR), and mixed reality.

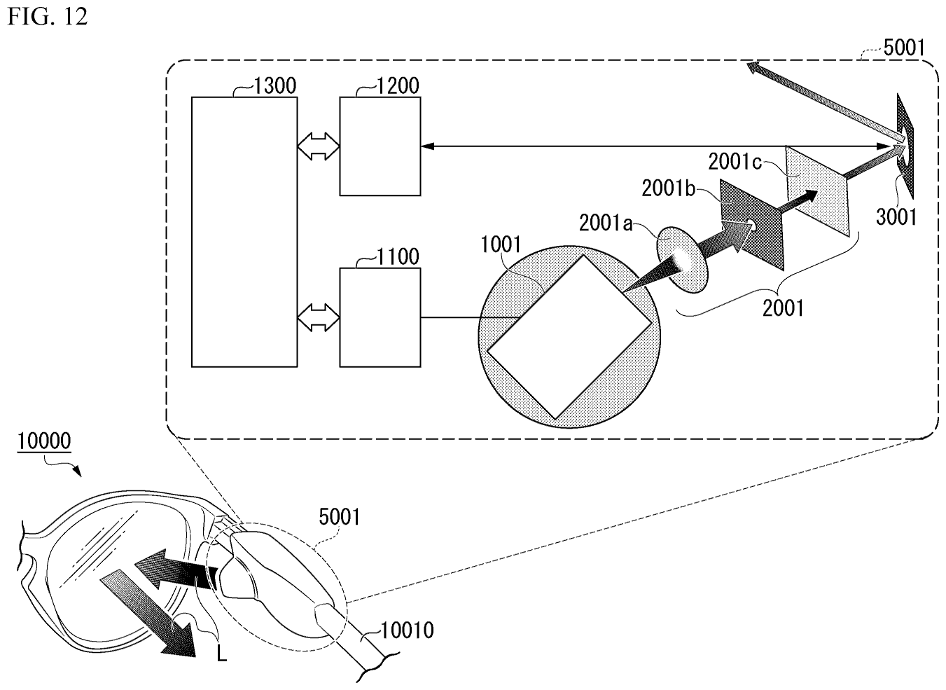

FIG. 12 shows an explanatory conceptual diagram of XR glasses according to the present embodiment.

In XR glasses 10000 shown in FIG. 12, a laser module 1001 is mounted in a frame 10010. The reference sign L indicates image display light.

In FIG. 12, the laser module 1001, an optical scanning mirror 3001, and an optical system 2001 connecting the laser module 1001 and the optical scanning mirror 3001 are collectively referred to as an optical engine 5001 in this specification. Any laser module according to the foregoing embodiment is used as the laser module 1001.

For example, a light source having the RGB laser elements including the red laser element 30-1, the green laser element 30-2, and the blue laser element 30-3, and the near infrared light laser element 35 can be used as a light source in the laser module 1001.

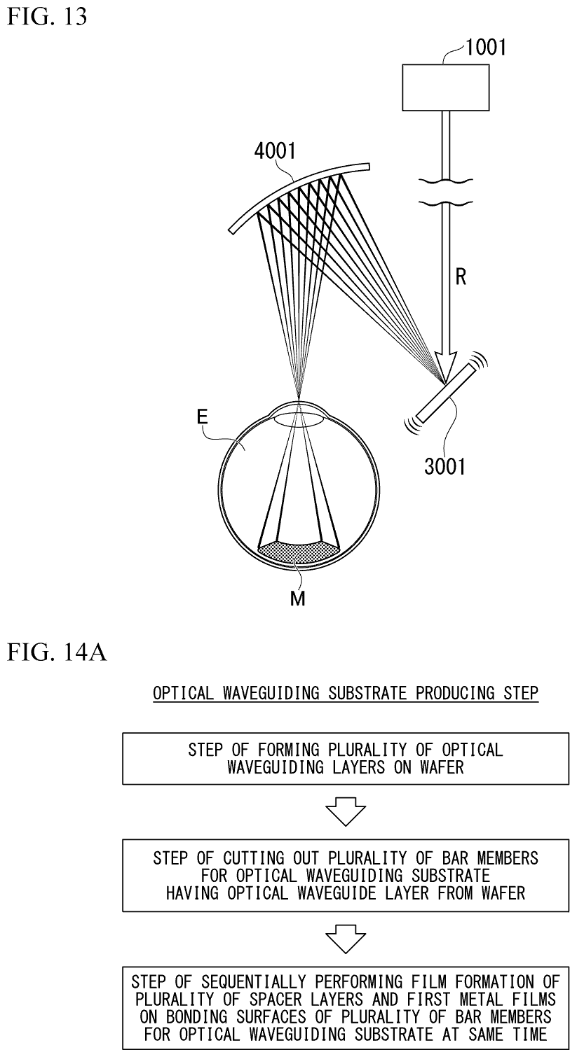

As shown in FIG. 13, irradiated laser light from the laser module 1001 attached to a glasses frame is reflected by the optical scanning mirror 3001, and the reflected light is reflected by a mirror 4001 reflecting it in the direction of a human eyeball E and enters the human eyeball E so that an image (video image) can be directly projected onto a By providing an eye tracking mechanism, an image is directly projected onto the retina while eye tracking is performed. A known mechanism can be used as the eye tracking mechanism. retina M.

For example, the optical scanning mirror 3001 is an MEMS mirror. In order to project a 2D image, it is preferable to use a two-axis MEMS mirror which vibrates so as to reflect laser light by changing the angle in a horizontal direction (X direction) and a vertical direction (Y direction).

The optical system 2001 optically processing laser light emitted from the laser module 1001 has a collimator Lens 2001a, a slit 2001b, and an ND filter 2001c. This optical system is merely an example and may have a different constitution.

The optical engine 5001 has a laser driver 1100, an optical scanning mirror driver 1200, and a video controller 1300 controlling these drivers.

### [Method for Manufacturing Laser Assembly]

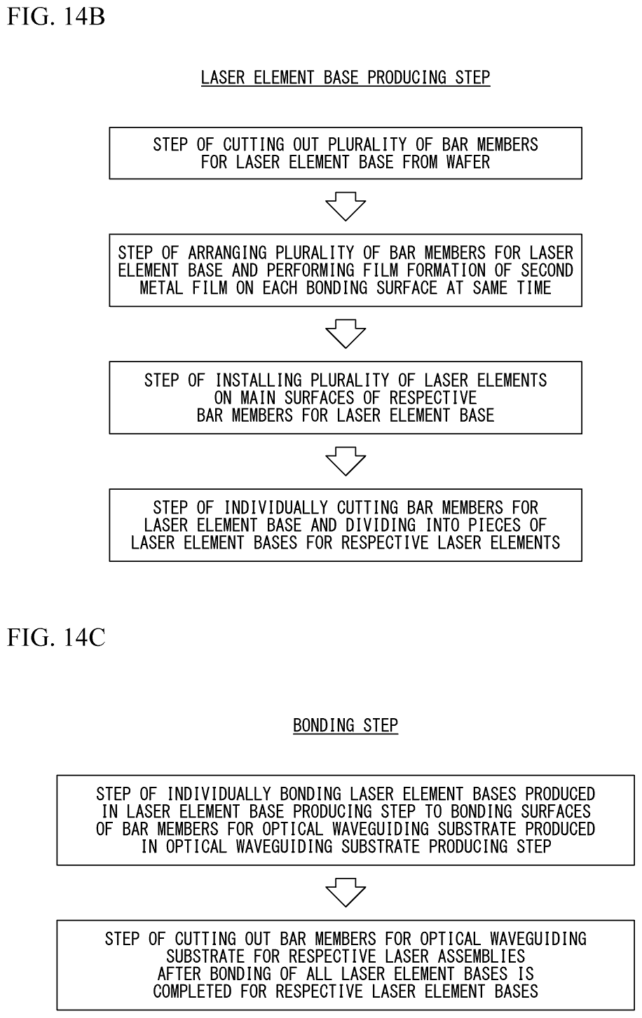

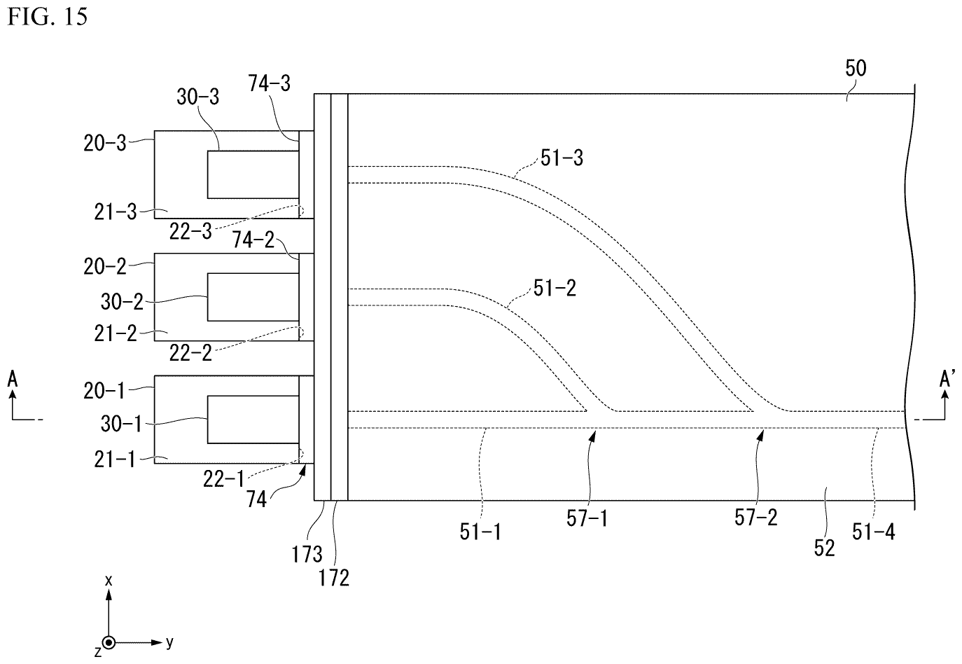

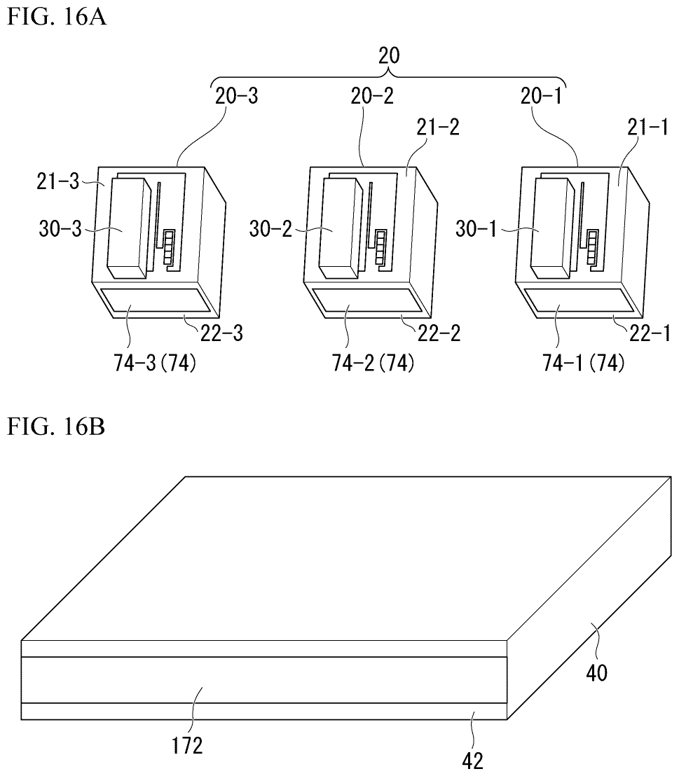

FIG. 14A to FIG. 14C show a flowchart of an example of a method for manufacturing a laser assembly.

The method for manufacturing a laser assembly has an optical waveguiding substrate producing step and a laser element base producing step, and a step of bonding an optical waveguiding substrate and laser element bases obtained from each of the steps.

As shown in FIG. 14A, in the optical waveguiding substrate producing step, first, a plurality of optical waveguiding layers are formed on a wafer. The plurality of optical waveguiding layers are optical waveguiding layers for all laser assemblies (the optical waveguiding layer 50 in FIG. 1) intended to be obtained from the wafer.

Next, the wafer is cut to cut out a plurality of bar members for an optical waveguiding substrate having an optical waveguiding layer on the main surface. Each of the plurality of cut-out bar members for an optical waveguiding substrate can include as many optical waveguiding layers as the number obtained by dividing the total number of laser assemblies intended to be obtained from a wafer by the number of bar members for an optical waveguiding substrate.

Next, using a photolithography technology, a laminated film having a spacer layer and a first metal film is formed on the bonding surface of each of the bar members for an optical waveguiding substrate. Specifically, the plurality of bar members for an optical waveguiding substrate are arranged, and film formation of the spacer layer and the first metal film is sequentially performed on the bonding surfaces thereof at the same time using a photoresist mask having a plurality of holes corresponding to the pattern of the plurality of spacer layers installed away from each other, thereby forming a laminated film including a spacer layer and a first metal film for each hole.

As shown in FIG. 14B, in the laser element base producing step, first, a wafer is cut to cut out a plurality of bar members for a laser element base.

Next, the plurality of bar members for a laser element base are arranged, and film formation of a second metal film is performed on each of the bonding surfaces at the same time. At this time, the second metal film may be subjected to film formation on the entire bonding surface of each of the bar members for a laser element base, or the second metal film may be subjected to film formation within a range narrower than the bonding surface. Since the bar members for a laser element base are cut into laser element bases for the respective laser elements afterward, the second metal film may be a continuous film for each of the bar members for a laser element base.

Next, a plurality of laser elements are installed on the main surfaces of the respective bar members for a laser element base.

Next, each of the bar members for a laser element base is individually cut to be divided into pieces of laser element bases for the respective laser elements.

As shown in FIG. 14C, the laser element bases produced in the laser element base producing step are individually bonded to the bonding surfaces of the bar members for an optical waveguiding substrate produced in the optical waveguiding substrate producing step.

Active alignment bonding can be used as bonding. Specifically, a current is supplied to an electrode provided on the laser element base, and a laser is oscillated therefrom in a state of being electrically connected to the laser element. In this state, it is brought closer while adjusting the position to the incidence port of the optical waveguide of the bar member for an optical waveguiding substrate. Further, the light intensity is monitored using a light sensor at the emission port, the position where the intensity is maximized is found, and the laser element base and the bar member for an optical waveguiding substrate are subjected to eutectic bonding at this position. For example, in eutectic bonding, a metal subjected to film formation on the bonding surface can be caused to melt by performing irradiation with a YAG laser.

Next, after bonding of all the laser element bases is completed for the respective laser element bases, the bar members for an optical waveguiding substrate are cut for the respective laser assemblies.

In this manner, a laser assembly is completed.

### EXPLANATION OF REFERENCES

20 Laser element base
30 Laser element
40, 140 Optical waveguiding substrate
50, 150 Optical waveguiding layer
100, 100B Laser assembly
110 Package
1000, 1001, 2000 Laser module
5001 Optical engine
10000 XR glasses

What is claimed is:

1. A laser assembly comprising:
a plurality of laser elements;
a plurality of laser element bases which have a main surface and a bonding surface and in which the plurality of laser elements are respectively installed on the main surfaces;
an optical waveguiding substrate which has a main surface and a bonding surface and in which an optical waveguiding layer is provided with optical waveguides for waveguiding laser light emitted from the plurality of laser elements on the main surface;
a plurality of spacer layers which are disposed away from each other at positions respectively corresponding to the plurality of laser element bases on the bonding surface of the optical waveguiding substrate; and
a plurality of metal laminate films which bond the bonding surfaces of the plurality of laser element bases and the bonding surface of the optical waveguiding substrate,
wherein the plurality of metal laminate films are respectively disposed on the plurality of spacer layers and have a plurality of first metal films and second metal films that are disposed on the bonding surfaces of the plurality of laser element bases and made of metals capable of being eutectic with metals constituting the first metal films.

2. The laser assembly according to claim 1,
wherein the first metal films are made of Sn or an alloy containing Sn, and the second metal films are made of a metal selected from the group consisting of Au, Si, Al, Ni, Zn, Pt, and alloys of these.

3. The laser assembly according to claim 1,
wherein the spacer layers have a thickness of 0.1 μm or larger.

4. The laser assembly according to claim 1,
wherein the spacer layers are made of a metal selected from the group consisting of Ta, Ti, Ni, Ta/Pt, Ti/Pt, and Ni/Pt.

5. The laser assembly according to claim 1,
wherein the spacer layers are made of an oxide.

6. The laser assembly according to claim 1,
wherein the second metal films are formed to have a larger area than the first metal films.

7. The laser assembly according to claim 1,
wherein the bonding surface of the optical waveguiding substrate includes an antireflection film, and the spacer layers are formed on the antireflection film.

8. The laser assembly according to claim 1,
wherein the optical waveguiding layer is a planar lightwave circuit (PLC) made of a glass material.

9. The laser assembly according to claim 1,
wherein the optical waveguiding layer is a PLC constituted of a lithium niobate film.

10. A laser module,
wherein the laser assembly according to claim 8 is accommodated inside a package.

11. A laser module,
wherein the laser assembly according to claim 9 is accommodated inside a package.

12. An optical engine comprising:
the laser module according to claim 10; and
an optical scanning mirror for scanning light emitted from the laser module.

13. An optical engine comprising:
the laser module according to claim 11; and
an optical scanning mirror for scanning light emitted from the laser module.

14. XR glasses comprising:
the optical engine according to claim 12.

15. XR glasses comprising:
the optical engine according to claim 13.

16. A method for manufacturing a laser assembly comprising:
an optical waveguiding substrate producing step of sequentially forming a plurality of spacer layers and first metal films on a bonding surface of an optical waveguiding substrate;
a laser element base producing step of forming second metal films on bonding surfaces of laser element bases; and
a bonding step of performing eutectic bonding of the laser element bases and the optical waveguiding substrate after the optical waveguiding substrate producing step and the laser element base producing step.

17. The method for manufacturing a laser assembly according to claim 16,
wherein in the optical waveguiding substrate producing step, the spacer layers and the first metal films are formed using a photoresist mask having a plurality of holes corresponding to a pattern of the plurality of spacer layers installed away from each other on the bonding surface of the optical waveguiding substrate, and
in the bonding step, eutectic bonding of the first metal films of the optical waveguiding substrate and the second metal films of the laser element bases is performed using active alignment bonding.
